(19) United States
(12) Patent Application Publication
(10) Pub. No.: US 2011/0127074 A1
(43) Pub. Date: Jun. 2, 2011

(54) METHOD FOR ROUGHENING TREATMENT OF COPPER FOIL AND COPPER FOIL FOR PRINTED WIRING BOARDS OBTAINED USING THE METHOD FOR ROUGHENING TREATMENT

(75) Inventor: Masaru Takahashi, Saitama (JP)

(73) Assignee: MITSUI MINING & SMELTING CO., LTD., Tokyo (JP)

(21) Appl. No.: 12/994,559

(22) PCT Filed: May 27, 2009
(86) PCT No.: PCT/JP2009/059651

§ 371 Date: Feb. 14, 2011

(30) Foreign Application Priority Data
May 28, 2008 (JP) 2008-140180

(51) Int. Cl. H05K 1/09; C25D 15/00

(52) U.S. Cl. 174/257; 205/109

(57) ABSTRACT

An object of the present invention is to provide a technology for forming a roughened surface of a copper foil which is laminated with an insulating resin substrate having a low dielectric constant, on which a fine-pitch wiring can be formed. To achieve the object, a method for roughening a surface of copper foil to be laminated with an insulating resin substrate characterized by depositing and forming of fine copper particles on the surface of copper foil, under conditions for burnt copper plating, using a sulfuric acid-based copper plating solution containing a quaternary ammonium salt polymer, is employed as a method for roughening treatment of a copper foil. Preferably, a solution temperature of the sulfuric acid-based copper plating solution of 20° C. to 40° C. and electrolysis is carried out with an average anode current density of 5 A/dm² to 40 A/dm² for a time period of 5 seconds to 20 seconds.

### TECHNICAL FIELD

The present invention relates to a method for roughening treatment of a copper foil and a copper foil for printed wiring boards obtained using the method for roughening treatment. More particularly, the invention relates to a method for roughening treatment of a copper foil, a copper foil for printed wiring boards obtained using the method for roughening treatment, a copper-clad laminate obtained using the copper foil for printed wiring boards, and a printed wiring board obtained using the copper-clad laminate. Especially, the invention relates to a method for roughening treatment of a copper foil for printed wiring boards suitable for a fine-pitch wiring.

### BACKGROUND ART

Due to the requirements for down-sizing of electronic devices through miniaturizing and weight reduction, cutting-edge printed wiring boards are required to meet the same requirements. In addition, higher the performance of information processing tools mounted on these electronic devices, use of a clock frequency of the handled signals more than 10 GHz is wide-spreading. As a result, a copper-clad laminate for manufacturing printed wiring boards is required to adopt an insulating resin substrate having a low dielectric constant. Many electronic devices with the reductions in size and weight tend to be mounted on a flexible printed wiring board on which fine-pitch wirings are formed. In addition, many package substrates for mounting ICs and LSIs adopt TCPs which are flexible printed wiring boards.

Typical insulating resin materials having a low dielectric constant include thermoplastic PPE (polyphenylene ether), PPO (polyphenylene oxide), fluororesins, and liquid-crystal polymers. However, these resins have been considered to be difficult to achieve a good and stable bonding strength with a copper foil for printed wiring boards. Especially, when a thermoplastic resin is used as a substrate, typical tendency to be instable in the bonding strength is observed.

The mechanism how the bonding strength between a copper foil and a resin substrate is achieved is that the level of bonding strength is estimated as sum of chemical bonding strength and physical bonding strength. According to the mechanism, in cases where a thermosetting resin is used as an insulating resin layer for laminating the copper foil, the chemical bonding strength can be stabilized by forming a layer of a silane coupling agent on a surface of the copper foil for matching a curing reaction of the resin. However, when a thermoplastic resin is used as an insulating resin layer for laminating the copper foil, the chemical bonding strength is hardly obtained as expected. Thus, in order to achieve a stable bonding strength with the copper foil, roughening treatment of the copper foil to achieve the physical bonding strength with an anchoring effect is made important.

In Patent Document 1, a surface-treated copper foil for a low-dielectric substrate that is used for lamination with the substrate which purpose is to provide the surface-treated copper foil which can secure an enough bonding strength to the low-dielectric substrate used for printed wiring board for a high frequency and minimize a transmission loss is disclosed. More particularly, a roughened layer composed of nodulous copper particles is formed on a copper foil surface followed by depositing ultrafine copper particles onto the entire surface of the roughened layer. The surface-treated copper foil has a surface roughness Rz of 1.0 to 6.5 μm and a surface color index L* of not greater than 50, a* of not greater than 20, and b* of not greater than 15. In the disclosure, a rust-proofing treated layer containing at least one selected from zinc and nickel is provided on the surface of the ultrafine copper particles deposited on the entire surface area of the nodulous copper particles of the roughened layer. According to the Examples, an electro-deposited copper foil having a nominal thickness of 12 μm with a surface roughness Rz of 3.5 μm and an electro-deposited copper foil having a nominal thickness of 35 μm with a surface roughness Rz of 4.6 μm were laminated with thermosetting PPO. It is reported that the copper foil with a thickness of 12 μm show peel strength of 0.72 kN/m and the copper foil with a thickness of 35 μm show peel strength of 1.00 kN/m.

According to the disclosure in Patent Document 2, a surface-treated copper foil which enables to provide composite substrate material having enough bonding strength with an insulating resin substrate and capable of forming a fine-pitch wiring by laminating the copper foil with a liquid-crystal polymer film which has a low moisture absorption and show an excellent heat resistance to the copper foil. The surface-treated copper foil has a roughened surface to which roughening particles are attached and the roughened surface has a surface roughness Rz of 1.5 to 4.0 μm and a brightness index of not greater than 30. In addition, it is preferable that protrusions composed of the roughening particles have a height of 1 μm to 5 μm, an approximately evenly distributed number is 6 to 35 pieces in an observed cross-sectional region of 25 μm, and a maximum width of the nodule is not less than 0.01 μm and not greater than twice a length of 25 μm divided by the number of pieces of the nodules in the region of 25 μm. According to the Example in Patent Document 2, it is reported that a peel strength of 0.55 kN/m to 1.31 kN/m was achieved when an electro-deposited copper foil of 12 μm having a surface roughness Rz of 2.5 μm to 3.7 μm and a brightness index of 16 to 23 were laminated with a liquid-crystal polymer film.

### DOCUMENTS CITED

### Patent Documents

[Patent Document 1] WO2003/102277
[Patent Document 2] Japanese Patent Laid-Open 2005-248323

### SUMMARY OF THE INVENTION

### Problems to be Solved

As described in Patent Document 2, even the bonding strength tends to be greater with a greater roughness of a roughened surface of a copper foil to be bonded with an insulating resin substrate for enhancing adhesion between the insulating resin substrate and the copper foil, a drawback making a fine-pitch wiring formation difficult is a common sense. For example, according to Comparative Example 7 in Patent Document 2, the surface of the copper foil laminated with the insulating resin substrate has a surface roughness Rz of 3.65 μm. Due to the greater roughness of the copper foil, a greater bonding strength (peel strength) between the copper foil and the insulating resin substrate is achieved. On the other hand, minimum line/space of the wiring formed by a subtractive method was 55 μm/55 μm (a wiring pitch of 110 μm). Also, it can be said in Example 2 of Patent Document 2 that the wiring formed by using a copper foil having the surface roughness of same level as that of Comparative Example 7 has a minimum line/space of 50 μm/50 μm (a wiring pitch of 100 μm). As is described above, it can be made obvious that a copper foil having a surface roughness Rz of not greater than 2.5 μm should be used for forming a wiring of 25 μm/25 μm (a wiring pitch of 50 μm).

When the surface roughness of a roughened surface of a copper foil able to be manufactured is estimated in the disclosures in Patent Document 1 and Patent Document 2, the surface roughness Rz is 1.0 to 6.5 μm in Patent Document 1, and the surface roughness Rz is 1.5 to 4.0 μm in Patent Document 2. In other words, the copper foil profile in Patent Document 1 is classified into Type V to Type L of IPC Standard and the copper foil profile in Patent Document 2 is classified into Type V. These copper foils are not popular copper foils for printed wiring boards, and are in the category of a low profile copper foil.

However, a wiring provided on a printed wiring board having an insulating layer of a liquid-crystal polymer as a TCP or a COF for mounting a LSI usually requires a wiring pitch of not greater than 50 μm. Such wiring pitch is hardly manufactured with stability by the technology disclosed in Patent Document 1 or Patent Document 2. Thus, a copper foil having a roughened surface which enables forming of a fine-pitch wiring having a wiring pitch of not greater than 50 μm has been required.

### Means to Solve the Problem

Therefore, through keen research, the present inventors have conceived a method for roughening treatment of a copper foil for a printed wiring board which enables forming a fine-pitch wiring, a copper foil for a printed wiring board obtained using the roughening treatment, a copper-clad laminate using the copper foil for a printed wiring board, and a printed wiring board using the copper-clad laminate as described below.

Method for roughening treatment of a copper foil according to the present invention: The method for roughening treatment of a copper foil according to the present invention is a method for roughening treatment of a copper foil to be laminated with an insulating resin substrate, characterized in that fine copper particles are formed by deposition on a surface of a copper foil by using a sulfuric acid-based copper plating solution containing a quaternary ammonium salt polymer.

Copper foil for printed wiring board according to the present invention: The copper foil having a roughened surface formed by using the method for roughening treatment is suitably used as a copper foil for a printed wiring board because the roughening treatment is uniform and dense.

Copper-clad laminate according to the present invention: The copper-clad laminate according to the present invention is characterized in using the copper foil having a roughened surface formed by the method for roughening treatment and is obtained by laminating the copper foil with an insulating resin substrate.

Printed wiring board according to the present invention: The printed wiring board according to the present invention is characterized by subjecting the copper-clad laminate to further processing such as etching.

### Advantage of the Invention

The method for roughening treatment of a copper foil according to the present invention is a method for roughening a surface of a copper foil to be laminated with an insulating resin substrate, wherein fine copper particles are formed by deposition on the surface of the copper foil by using a prescribed sulfuric acid-based copper plating solution. By the method for roughening treatment, a dense and uniform roughening treatment can be performed on the surface of the copper foil. The copper foil having such a roughened surface is suitably used as a copper foil for printed wiring boards. By adopting the roughened surface of the copper foil roughened by the method for roughening treatment according to the present invention as a bonding surface to an insulating resin substrate, good adhesion with the insulating resin substrate composed of a thermoplastic resin having a low dielectric loss is provided. Thus, the copper foil is suitably used for manufacturing a printed wiring board with the roughened surface suitable for forming a fine-pitch wiring.

### BRIEF DESCRIPTION OF DRAWINGS

FIG. 1 is an observed SEM image of a roughened surface of Sample 1.

### BEST MODE FOR CARRYING OUT THE INVENTION

To make understanding of the method for roughening treatment of a copper foil according to the present invention easy, a popular method of manufacturing an electro-deposited copper foil for printed wiring boards will be reviewed for confirmation. In the present invention, the term “copper foil” includes any concept of an electro-deposited copper foil, a rolled copper foil, and a copper foil with carrier.

First, a process for manufacturing an electro-deposited copper foil will be summarized. As for the electro-deposited copper foil, copper is first electro-deposited on a rotating cathode to form a foil, which is then wound up for collection. In this step, the foil may be referred to as “untreated electro-deposited copper foil”, because no surface treatment is provided. Subsequently, the electro-deposited copper foil is subjected to surface treatments such as roughening treatment and rust-proofing treatment to provide a required quality and product of the electro-deposited copper foil is finished. Accordingly, an “electro-deposited copper foil” referred to in the market is, in a strict sense, a “surface-treated electro-deposited copper foil”, of which surface is treated.

On the other hand, in the case of rolled copper foil, a copper ingot having composition required to an intended end-usage is prepared. The copper ingot is repeatedly rolled with applied pressure and heat-treated to finish a copper foil with a predetermined thickness. The rolled copper foil in this step may be referred to as “untreated rolled copper foil”, because no surface treatment is provided. Subsequently, similarly to the case of electro-deposited copper foil, the rolled copper foil is subjected to surface treatment such as roughening treatment and rust-proofing treatment to provide a required quality and a product of the rolled copper foil is finished. Accordingly, a “rolled copper foil” referred to in the market is, in a strict sense, a “surface-treated rolled copper foil”, of which surface is treated.

### [Method for Roughening Treatment of a Copper Foil According to the Present Invention]

The method for roughening treatment of a copper foil according to the present invention is a method for roughening a surface of a copper foil to be laminated with an insulating resin substrate. The method for roughening treatment of a copper foil will be demonstrated below in detail.

The method for roughening treatment of a copper foil according to the present invention is basically composed of electrolysis under burnt copper plating conditions using a sulfuric acid-based copper plating solution containing a quaternary ammonium salt polymer and fine copper particles are formed by deposition on a surface of a copper foil. In the popular methods disclosed in Patent Document 2, the copper roughening particles are formed by deposition on a matte side of an electro-deposited copper foil. The reason is that the burnt copper plating tends to make a current concentrate at the peak tops of the bumps. On the other hand, the roughening treatment according to the present invention enables uniform and fine copper particles deposition on a bump-free, flat surface of an electro-deposited copper foil or a rolled copper foil because a sulfuric acid-based copper plating solution containing a quaternary ammonium salt polymer is used. In other words, uniform and fine burnt plated copper particles deposition can be achieved even on a flat surface when a predetermined sulfuric acid-based copper plating solution is used and optimum solution temperature and current density is set.

The sulfuric acid-based copper plating solution used in the method for roughening treatment of a copper foil according to the present invention will be described. The sulfuric acid-based copper plating solution used in the present invention contains a quaternary ammonium salt polymer. By using the quaternary ammonium salt polymer, even on the surface of an untreated copper foil to be a cathode which has bumps of single μm height where current concentration may hardly be generated, the fine copper particles can be uniformly deposited on the surface without unevenly distributed deposition of the fine copper particles on a common surface. In other words, since deviation in the shape and size of the fine copper particles formed by deposition in the burnt copper plating conditions is made small, the preferable fine copper particles can be steadily formed by deposition. In addition, just a small amount of the quaternary ammonium salt polymer is required for adding to the sulfuric acid-based copper plating solution. Although the polymer is a component adsorbing to a copper surface, the conductivity of the finished copper foil is not affected because the amount of impurities incorporated into the deposited fine copper particles is small.

Furthermore, a quaternary ammonium salt polymer as an additive is preferable for reducing a load of waste-water treatment. For example, in Patent Document 1 using a metal salt as an additive, deposition of a hard copper alloy particles is achieved with addition of As, which has a recognized effect on stabilization of the deposition state of roughening copper particles, is proposed. However, the use of As might be ruled out due to a larger load of waste-water treatment with increased manufacturing cost, and potentiality of harm on human health. Accordingly, a quaternary ammonium salt polymer is selectively used as an additive which enables the stable burnt copper plating with the less load of waste-water treatment and with the less harm on human health.

Among the quaternary ammonium salt polymers, the polymers having a chemical structure with a straight-chain composed of hydrocarbon achieve more stable effect. A quaternary ammonium salt polymer having either structure of a cyclic structure or straight-chain structure is applicable. In the quaternary ammonium salt polymer having a straight-chain structure, it is preferable that a structure of quaternary ammonium salt is included in the main chain. When a quaternary ammonium salt polymer having a cyclic structure is used, it is preferable that a diallyl dimethylammonium chloride polymer having a cyclic structure of not smaller than a dimer is used. A diallyl dimethylammonium chloride polymer forms a cyclic structure when polymerized and a part of the cyclic structure is composed of nitrogen atoms of a quaternary ammonium. By the way, diallyl dimethylammonium chloride polymers having a cyclic structure have more than one formulation, with the cyclic structures such as a five-membered ring and a six-membered ring. It is believed that an actual polymer is composed of either one or mixture of them depending on the polymerization conditions. Accordingly, a compound having a five-membered ring structure with a chloride ion as a counter-ion is represented by Formula 1 as a typical example among these polymers.

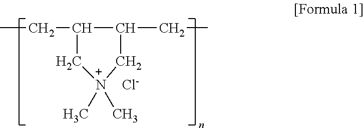

It is also preferable that halogen ions in the “sulfuric acid-based copper plating solution containing a quaternary ammonium salt polymer” used in the method for roughening treatment of a copper foil according to the present invention are controlled within a certain range. Halogen ions also have a property to adsorb to copper. Under the same condition, iodine ions, bromine ions, chloride ion, and fluorine ions have adsorption capability in this order. However, when a balance in consideration of the handling ability and the intended use for the plating solution containing a large amount of sulfate ions, it can be said that the use of chloride ion makes the adsorption state the most stable. Hereinafter, descriptions will be limited to chloride ion.

Since the chloride ion in the sulfuric acid-based copper plating solution adsorb to a surface of the deposited metal copper in a copper plating step to perform an effect of improving uniformity of the surface state, it is preferable to use with an organic additive. When a quaternary ammonium salt polymer is used in combination with chloride ion, chloride ion adsorbs to copper to perform an effect of moderately suppressing electro-deposition of copper to the surface of copper. Therefore, in the case of producing a copper-plating layer with a flat surface, chloride ion concentration is often made to control. Due to the coexistence of a quaternary ammonium salt polymer and chloride ion in a solution as described above, chloride ion adsorbed on the surface of the copper foil move to the deposited surface along with a change in surface potential resulting from the deposition of copper particles. Thus, the adsorbed chloride ion consistently exists on the top layer. Consequently, when a quaternary ammonium salt polymer adsorb to the surface of deposited copper, the possibility of incorporating the quaternary ammonium salt polymer into the deposited copper is reduced to favorably prevent the purity of deposited copper made poor.

By using the sulfuric acid-based copper plating solution in which a quaternary ammonium salt polymer and chloride ion coexist (burnt copper plating solution), the fine copper particles can be uniformly deposited on the surface in more stabilized conditions without unevenly distributed deposition of the fine copper particles on a common surface. In other words, since deviation in the shape and size of the fine copper particles formed by deposition in the burnt copper plating conditions is made small, the preferable fine copper particles can be steadily formed by deposition. Although the quaternary ammonium salt polymer is a component adsorbing to copper, just a small amount in the range from 0.1 mg/L to 50 mg/L is required to add. Thus, the conductivity of the finished copper foil is not affected because the amount of impurities incorporated into the deposited fine copper particles is small.

Moreover, the composition of the sulfuric acid-based copper plating solution in which a quaternary ammonium salt polymer and chloride ion coexist will be specifically described. For the method for roughening treatment of a copper foil according to the present invention, the sulfuric acid-based copper plating solution is preferable to have a copper concentration of 5 g/L to 20 g/L, a sulfuric acid concentration of 50 g/L to 150 g/L, a quaternary ammonium salt polymer concentration of 0.1 mg/L to 50 mg/L, and a chloride ion concentration of 1 mg/L to 100 mg/L.

The preferable copper concentration range is from 5 g/L to 20 g/L. Even in the case of a copper concentration of less than 5 g/L, fine copper particles can be formed by deposition on the surface of copper foil. However, a lower electrolytic current density is required for forming a good shape of particles in the subsequent step of copper seal plating and makes productivity poor. So, it is not preferable. In addition, the lower copper concentration reduces cathode current efficiency and tends to make deviation in size and distribution of the fine copper particles formed by deposition large. On the other hand, a copper plating solution with a copper concentration of more than 20 g/L is not preferable, because a higher electrolytic current density is required to achieve depositing and forming of the fine copper particles on a surface of an untreated copper foil.

Then, the sulfuric acid concentration is preferable to be in the range from 50 g/L to 150 g/L. Within the range of sulfuric acid concentration as described above, an electrolysis voltage can be stabilized and the electrolysis current may not be fluctuated. So, it is preferable. A sulfuric acid concentration of more than 150 g/L is not preferable, because the effect to lower electrolysis voltage is reduced while management cost increases.

The quaternary ammonium salt polymer concentration is preferable to be in the range from 0.1 mg/L to 50 mg/L. A quaternary ammonium salt polymer concentration of less than 0.1 mg/L is not preferable. Due to the low content of the quaternary ammonium salt polymer, the quaternary ammonium salt polymer cannot adsorb enough to the surface of copper foil and sufficient effect for making deposition of fine copper particles uniform may not be performed. On the other hand, when a quaternary ammonium salt polymer concentration exceed 50 mg/L, the content of quaternary ammonium salt polymer is just excess and may cause coated state with an excess adsorption of the quaternary ammonium salt polymer at some portion of the surface of copper foil. As a result, it may obstruct the effect of uniform deposition of fine copper particles. Concurrently, the content of impurities incorporated into the fine copper particles deposited increases to make the conductivity of the finished copper foil poor.

Furthermore, the chloride ion concentration is preferable to be in the range from 1 mg/L to 100 mg/L. A chloride ion concentration of less than 1 mg/L creates difficulty of achieving the state in which chloride ion uniformly adsorb to a surface of copper foil. As a result, even with the quaternary ammonium salt polymer concentration in the optimum range, the effect to make the deposition of fine copper particles when using the quaternary ammonium salt polymer as an additive is suppressed. So, it is not preferable. On the other hand, a chloride ion concentration of more than 100 mg/L is not preferable, because the effect of addition of chloride ion is saturated while bad influence such as corrosion of the facilities might be caused.

Next, an electrolysis condition in the method for roughening treatment of a copper foil according to the present invention will be described. In this step, by using the copper-plating solution, fine copper particles are uniformly formed by deposition on a surface of the untreated copper foil. In the roughening step and the copper seal plating step to be described below, the electrolysis condition with an arrangement of a copper foil as cathode and a counter electrode of insoluble anode will be demonstrated.

In the preferable conditions of the electrolysis for the roughening treatment, the copper plating solution having a solution temperature of 20° C. to 40° C. is adopted with an anode current density of 5 A/dm² to 40 A/dm². First, the solution temperature will be described. A solution temperature for the copper plating solution of lower than 20° C. is not preferable, because the deposition rate may decrease and the shape of deposited copper particles tends to be made too small. On the other hand, a solution temperature for the copper plating solution of higher than 40° C. is not preferable, because maintenance of the condition for the burnt copper plating in the range of copper concentration is made difficult. Thus, solution temperature range from 20° C. to 40° C. is advantageous for the industrial production.

It is preferable to adopt an average anode current density of 5 A/dm² to 40 A/dm² for the roughening treatment. With an anode current density of lower than 5 A/dm², the fine copper particles steady and uniform are hard to be formed by deposition. On the other hand, an anode current density of higher than 40 A/dm² is not preferable, because the deviation in the size of deposited copper particles is made large.

It is preferable to carry out the burnt copper plating electrolysis for the roughening treatment in several steps, i.e., not less than two steps. The reason is that although spots where a current concentrate may be generated in burnt copper plating, the generation can be suppressed. As a condition of the burnt copper plating electrolysis carried out in the second step or later steps, it is preferable to use the copper plating solution having a solution temperature of 20° C. to 40° C. with an average anode current density of 5 A/dm² to 40 A/dm². It is preferable to make the current density of the burnt copper plating carried out in the second step or later steps lower than that of the burnt copper plating carried out in the first step. In the case where the current density for the second step or later steps is equal to and lower than that for the first burnt copper plating, the above-mentioned additive has an effect making copper plating level. Consequently, copper preferentially deposits on smaller copper particles among the fine copper particles formed by deposition for the first time to have an effect to level the size of copper particles.

In the burnt copper plating for the roughening treatment, the total time period of electrolysis for the first step and second step or later steps is preferable in the range from 5 seconds to 20 seconds. With a total time period of electrolysis of less than 5 seconds, the fine copper particles formed by deposition on the surface of copper foil are too small and, in certain situations, a surface after deposition is made similar to a smooth surface without roughening treatment. So, it is not preferable because no anchor effect to a resin substrate is obtained. On the other hand, with a total time period of electrolysis of more than 20 seconds, the fine copper particles formed by deposition on the surface of copper foil are made big. Thus, the deviation in levels of the roughening treatment is made large by portion in a common surface. So, it is not preferable because the roughening treatment makes forming of a fine-pitch wiring difficult.

In addition to the above-mentioned roughening treatment, it is also preferable to form a “copper seal plating layer” on the surface of copper foil composed of the fine copper particles formed by deposition using a sulfuric acid-based copper plating solution under a condition for level copper plating. To stabilize the adhesion state of the fine copper particles formed by deposition on the copper foil through the roughening treatment, the surfaces of the fine copper particles and the copper foil are coated with a continuous copper layer to make the shape of fine copper particles preferable. Concurrently, a drop-off of the fine copper particles can be prevented.

As preferable conditions for the formation of the “copper seal plating layer”, the sulfuric acid-based copper plating solution with a copper concentration of 45 g/l to 100 g/l and a sulfuric acid concentration of 50 g/l to 150 g/l having a solution temperature of 20° C. to 60° C., and electrolysis with an average anode current density of 5 A/dm² to 30 A/dm² is carried out at least one time with a total time period of electrolysis of 5 seconds to 60 seconds. As for the sulfuric acid-based copper plating solution used, with precondition of employing the above-mentioned current density, any specific limitation is required except that a solution composition never generate burnt copper plating on the surface of fine copper particles formed by deposition through the roughening treatment. Although any particular additive may not required in the sulfuric acid-based copper plating solution for the copper seal plating, but a solution containing halogen ions such as chloride ion may enable to obtain more uniform copper seal plating layer. The copper seal plating is carried out under conditions of level copper plating, and the electrolysis may be carried out in several steps.

The solution temperature of the copper plating solution used for the copper seal plating is preferable to be in the range from 20° C. to 60° C. In the case of using the copper plating solution with the above-mentioned composition, a solution temperature of the solution of lower than 20° C. is not preferable, because crystalline of copper sulfate deposits in some cases, the high concentrations of both the sulfuric acid and the copper in the sulfuric acid-based copper plating solution. On the other hand, a solution temperature of the plating solution of higher than 60° C. is not preferable, because composition concentrations fluctuate in a short time period due to a large amount of evaporation of water. Although the fluctuation of the concentration rarely cause a bad effect on the state of the seal plating, but crystalline of copper sulfate tends to deposit due to the increased concentrations of sulfuric acid and copper. So, it is not preferable.

It is preferable to deposit and form the finer or ultrafine copper particles on the surface of the fine copper particles formed through the roughening treatment described above. This step is carried out optionally, with consideration for the adhesion property of an insulating resin substrate to be laminated. However, the deposition and formation of the fine copper particles on the level plated copper seal plating layer broaden the contact area with an insulating resin substrate. Consequently, the effect of further stabilizing a bonding strength to a thermoplastic resin, to which the chemical bonding strength is not highly expected, can be achieved.

Several methods can be adopted for depositing and forming of finer, or ultrafine copper particles on a surface of the fine copper particles formed through the roughening treatment. Among the methods, it is also preferable to use the copper plating solution containing a quaternary ammonium salt polymer for depositing and forming of the ultrafine copper particles when the ultrafine copper particles are deposited to form on the surface of the fine copper particles. The reason is that by using the copper plating solution containing a quaternary ammonium salt polymer for forming the ultrafine copper particles, a preferable state of roughening treatment is achieved with a uniformed size of ultrafine copper particles.

Copper foil for printed wiring board according to the present invention: The copper foil for printed wiring board according to the present invention is a surface-treated copper foil produced through the method for roughening treatment of a copper foil which is used as the copper foil for a printed wiring board. Onto the roughened surface of the surface-treated copper foil produced through the above-mentioned method for roughening treatment, fine copper particles having a uniform particle size are attached uniformly. Consequently, when the surface-treated copper foil is laminated with an insulating resin substrate constituting a copper-clad laminate or a printed wiring board, the broad surface area of the bonding interface between the insulating resin substrate and the surface-treated copper foil enhances the adhesion. Thus, even in a chemical treatment provided in a manufacturing process of a printed wiring board, chemical attack from edge of the wiring is prevented. In addition, since the copper particles are fine, forming of a fine-pitch wiring is made easy.

The copper foil for a printed wiring board in the present description includes concept such as a copper foil having a roughened surface on which a rust-proofing treatment layer may be formed or a silane coupling agent treatment may be provided according to an intended end-use of various printed wiring boards, as required.

Copper-clad Laminate according to the present invention: The copper-clad laminate according to the present invention is a copper-clad laminate obtained by laminating the copper foil for a printed wiring board with an insulating resin substrate. As described above, as for the copper-clad laminate using the copper foil for a printed wiring board, forming of a fine-pitch wiring is made easy in any type of the insulating resin substrate. In addition, the copper-clad laminate has an excellent chemical resistance and surface migration resistance. In a copper-clad laminate composed of an insulating resin substrate including a reinforcement such as glass cloth, contact points of the formed wiring and the reinforcement are a few. As a result, a copper-clad laminate which enables production of a printed wiring board with an excellent CAF resistance can be provided.

In the copper-clad laminate according to the present invention, it is also preferable to use a liquid-crystal polymer as the insulating resin substrate. As described above, for a high-frequency flexible printed wiring board, a liquid-crystal polymer is used in many situations due to both advantages of an excellent folding endurance and small water absorption. Since the liquid-crystal polymer substrate laminated with the copper foil for a printed wiring board according to the present invention has a good high frequency performance with small water absorption, the substrate is suitably used for manufacturing a flexible printed wiring board and a TCP with long-term reliability.

Printed wiring board according to the present invention: The printed wiring board according to the present invention is a printed wiring board produced by further processing the copper-clad laminate, etching and the like. As described above, a fine-pitch wiring can be formed on the printed wiring board, which has a sufficient practical bonding strength, an excellent chemical resistance, a surface migration resistance, and CAF resistance. Thus, a printed wiring board having a good reliability for a long-term use can be provided.

### Example

In the Example, 3 types of surface-treated copper foils (Sample 1 to Sample 3) were prepared through roughening treatment, rust-proofing treatment, and silane coupling agent treatment onto the deposit side surface of untreated electro-deposited copper foil with a nominal thickness of 12 μm (surface roughness Rzjis=0.6 μm). Here, electrolysis for burnt copper plating was carried out for forming fine copper particles. Subsequently, copper seal plating was carried out. Each composition of the electrolysis solution for the burnt copper plating and the copper seal plating is shown in Table 1 and the condition of electrolysis is shown in Table 2.

The prepared surface-treated copper foils were evaluated with “surface roughness (Rzjis)” and “estimated surface area ratio (B) which is (A)/6550, where (A) is the three-dimensional surface area in μm² measured by a laser method and 6550 is a two-dimensional measured area in μm²”. The evaluation methods corresponding to the evaluation items will be described below.

Surface roughness: The surface roughness (Rzjis) of the surface-treated copper foil was measured with a stylus-type surface roughness measuring instrument SE3500 made by Kosaka Laboratory Ltd, which has a diamond stylus with a tip curvature radius r of 2 μm, according to JIS B 0601. The result of evaluation is shown in Table 3.

Surface area ratio: The three-dimensional surface area of the surface-treated copper foil was measured for a two-dimensional area of 6550 μm² with an ultra-high depth color 3D shape measuring microscope VK-9500 made by Keyence Corporation (laser used: visible violet laser wavelength of 408 nm) to estimate the surface area ratio. The result of evaluation is shown in Table 3.

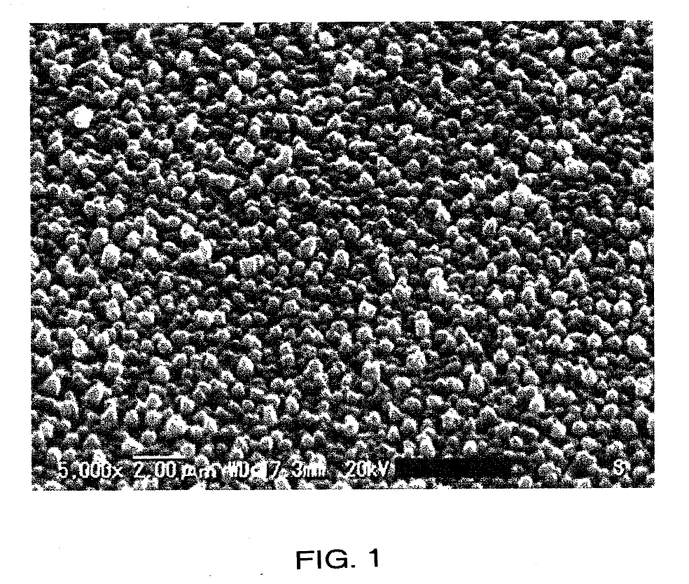

View of the roughened surface: A scanning electron microscope image of an electro-deposited copper foil (Sample 1) of which surface was roughened by the method for roughening treatment according to the present invention is shown in FIG. 1.

Peel strength: On the roughened surfaces of Sample 1 to Sample 3 prepared in the Example, rust-proofing treatment and silane coupling agent treatment were carried out to finish surface-treated copper foils. Each of the surface-treated copper foils was laminated with a commercially-available liquid-crystal polymer substrate to make a single-side copper-clad laminate through hot pressing with a vacuum press machine. Subsequently, the surface of the copper foil of the single-side copper-clad laminate was polished, and a dry film was laminated to the entire surface. On the dry film, a mask film to form a wiring pattern for evaluation was placed for carrying out exposure and development. After finishing development, unexposed portions of the dry film were removed to obtain an etching resist. Subsequently, the portions of copper foil without the etching resist were etched using cupric chloride etching solution. Furthermore, the etching resist was removed to prepare a test coupon for the evaluation of adhesion having a straight wiring with a width of 10 mm for the measurement of peel strength. The peel strength of the test coupon was measured with a universal testing machine based on JIS C 6481. The result of evaluation is shown in Table 3.

TABLE 1

| | Copper Plating Solution | | | | Copper seal | |
|---|---|---|---|---|---|---|
| | for Roughening Treatment | | | | plating Solution | |
| | Copper | Sulfuric Acid | Chlorine | | Copper | Sulfuric Acid |
| | Concentration | Concentration | Concentration | DDAC* | Concentration | Concentration |
| | g/L | | mg/L | | g/L | |
| Example | 9 | 95 | 50 | 10 | 60 | 120 |

*DDAC: Concentration of Diallyl Dimethylammonium Chloride Polymer Having a Cyclic Structure

TABLE 2

| | | Conditions of Copper Plating | | | Conditions of Copper | | |
|---|---|---|---|---|---|---|---|
| | | for Roughening Treatment | | | seal plating | | |
| | | | Anode | | | Anode | |
| | | Solution | Current | | Solution | Current | |
| | | temperature | Density | Time Period | temperature | Density | Time Period |
| | | ° C. | A/dm² | Second | ° C. | A/dm² | Second |
| Example | Sample 1 | 30 | 8 | 8 | 50 | 8 | 10 |
| | Sample 2 | | 12 | | | | |
| | Sample 3 | | 16 | | | | |

TABLE 3

| | | Surface | Evaluation Item | |
|---|---|---|---|---|
| | | Roughness* | Surface area ratio | Peel Strength** |
| | | μm | — | kgf/cm |
| Example | Sample 1 | 0.71 | 1.29 | 0.85 |
| | Sample 2 | 0.80 | 1.37 | 1.08 |
| | Sample 3 | 1.18 | 1.68 | 1.07 |

*Value of Rzjis
**Measured value for a 10 mm-wide straight wiring.

The fine copper particles of the surface-treated copper foil prepared in Example are a big-nodule free, smooth roughened surface as shown in FIG. 1, regardless of the electrolysis carried out under conditions of burnt copper plating. In addition, as can be understood in Table 3, the surface roughness as a surface-treated copper foil has a low profile level which enables the formation of a fine-pitch wiring, those are proof of that a fine and uniform roughened surface can be formed.

Furthermore, as shown in Table 3, although the roughening treatment of the surface-treated copper foil according to the present invention is provided with a low profile, excellent peel strength of not less than 0.8 kgf/cm is achieved due to a high surface area ratio.

### INDUSTRIAL APPLICABILITY

The method for roughening treatment of a copper foil according to the present invention is a method suitable for roughening a surface of a copper foil for a printed wiring board to be laminated with an insulating resin substrate. The copper foil roughened by the method exhibits an excellent adhesion to a low dielectric insulating resin substrate, and a roughened surface is suitable for forming a fine-pitch wiring. Specifically, the fine copper particles properly combined with rust-proofing makes an adhesion to a thermoplastic resin of which adhesion to a copper foil is poor good. Thus, manufacturing of a copper-clad laminate using an insulating resin substrate with a low dielectric loss performance is made easy. In addition, since the copper foil roughening treatment is carried out with fine and uniform copper particles, a printed wiring board for high-frequency signals having a fine-pitch wiring is made easy also.

1. A method for roughening treatment of a copper foil to be laminated with an insulating resin substrate, characterized in that fine copper particles are formed by deposition on a surface of a copper foil by using a sulfuric acid-based copper plating solution containing a quaternary ammonium salt polymer.

2. The method for roughening treatment of a copper foil according to claim 1, wherein the quaternary ammonium salt polymer is a diallyl dimethylammonium chloride polymer having a cyclic structure.

3. The method for roughening treatment of a copper foil according to claim 1, wherein the sulfuric acid-based copper plating solution contains halogen ions.

4. The method for roughening treatment of a copper foil according to claim 1, wherein solution temperature of the sulfuric acid-based copper plating solution of 20° C. to 40° C. and electrolysis is carried out with an average anode current density of 5 A/dm² to 40 A/dm² for a time period of 5 seconds to 20 seconds.

5. A copper foil for a printed wiring board characterized in that the copper foil is obtained by the method for roughening treatment of a copper foil according to claim 1.

6. A copper-clad laminate characterized in that the laminate is obtained by laminating the copper foil for a printed wiring board according to claim 5 with an insulating resin substrate.

7. A printed wiring board characterized in that the printed wiring board is obtained by using the copper-clad laminate according to claim 6.
